(19) United States
(12) Patent Application Publication
(10) Pub. No.: US 2015/0176122 A1
(43) Pub. Date: Jun. 25, 2015

(54) Low-temperature growth of complex compound films

(71) Applicant: Intermolecular Inc., San Jose, CA (US)

(72) Inventors: Chien-Lan Hsueh, Campbell, CA (US); Tony P. Chiang, Campbell, CA (US); Randall J. Higuchi, San Jose, CA (US); Kurt Pang, Fremont, CA (US)

(73) Assignee: Intermolecular Inc., San Jose, CA (US)

(21) Appl. No.: 14/136,384

(22) Filed: Dec. 20, 2013

(51) Int. Cl. C23C 16/44

(52) U.S. Cl. CPC C23C 16/44

(57) ABSTRACT

Ternary oxides, nitrides and oxynitrides of the form (a)(b)OₓN_{y} are formed by ALD or CVD when the reaction temperature ranges of the (a) precursor and the (b) precursor do not overlap. Chemically-reacted sub-layers, e.g., (a)OₓN_{y}, are formed by reacting the lower-temperature precursor with O and/or N at a temperature within its reaction range. Physisorbed sub-layers (e.g., (b) or (b)+ligand) are formed between the chemically-reacted sub-layers by allowing the higher-temperature precursor to physically adsorb to the low-temperature surface. When the desired sub-layers are formed, the substrate is heated to a temperature at which the higher-temperature precursor reacts (optionally in the presence of more O and/or N) to form (a)(b)OₓN_{y}. Quarternary and more complex compounds can be similarly formed.

### BACKGROUND

Related fields include thin-film formation by atomic layer deposition (ALD), chemical vapor deposition (CVD), and related techniques; in particular, formation of ternary, quarternary and higher-order oxides, nitrides, and oxynitrides of components with differing reaction temperatures.

Advanced thin-film devices can only benefit from new materials if those materials can be reliably produced. Oxides, nitrides and oxynitrides of mixed materials show promise, for example, as variable-resistance and constant-resistance layers of resistive-switching memory (sometimes called “ReRAM”), and in other applications. In some of the applications, stoichiometric oxygen and/or nitrogen content is desirable; in others, non-stoichiometric variations are preferred. However, some of these complex compounds can be difficult to deposit or grow in the desired ratios of the different elements.

For example, consider tantalum silicon nitride (TaSiN). With fairly high Si content, it works well as a constant-resistance layer or “embedded resistor” in a ReRAM stack. However, the Si precursor tris(dimethylamino)silane (TDMAS) will only react with the N precursor NH₃ to form SiN at a process temperature greater than 500 C, while the Ta precursor (tert-butylimido)tris(diethylamido)tantalum(V) (TBTDETa) decomposes at temperatures above about 340 C. This disparity in tolerable temperature range poses serious obstacles to conventional co-deposition.

Therefore, a need exists for a way to form oxide, nitride, or oxynitride of complex compounds despite disparities in reaction temperatures of the various components.

### SUMMARY

The following summary presents some concepts in a simplified form as an introduction to the detailed description that follows. It does not necessarily identify key or critical elements and is not intended to reflect a scope of invention.

Embodiments of methods of forming films of complex (ternary and higher-order) oxide, nitride, or oxynitride include identifying the precursor(s) with the lowest tolerated temperature range required to form the film (the “low-temperature precursor” or LTP). A substrate may be prepared in a chamber at a temperature within the LTP's tolerated temperature range. A chemically-reacted seed sub-layer of the oxide, nitride, or oxynitride of the LTP's deposited material is formed on the substrate. One or more precursors for other components (the “high-temperature precursor” or HTP whose minimum reaction temperature is higher than the highest temperature tolerated by the LTP) are introduced into the chamber without heating the substrate to the HTP's minimum reaction temperature. Although the substrate is too cool for the HTP to react, some of the HTP physically adsorbs (“physisorbs”) onto the seed sub-layer, forming a physisorbed sub-layer. Chamber pressure may be between about 1 and 1.5 Torr to encourage physisorption and coverage of any 3D structures on the substrate.

More reacted LTP oxide, nitride, or oxynitride sublayers and physisorbed HTP sub-layers of HTP may be alternatingly deposited to form a laminate of a desired thickness (e.g., between 3 nm and 20 nm). In some embodiments, the distribution of layers in the laminate or the composition of the Si precursor may be modulated to tune Si content. The laminate may then be annealed. Generally, the deposited oxide, nitride, or oxynitride from reacted LTP is more temperature-tolerant than its precursor, so the anneal temperature can be hot enough to cause the physisorbed precursors to react. Materials from the sublayers may at least partially interdiffuse during the anneal. Optionally, to increase nitrogen content in the oxide, nitride, or oxynitride, the nitrogen content can be increased by annealing in a nitrogen-containing ambient.

### BRIEF DESCRIPTION OF DRAWINGS

The accompanying drawings may illustrate examples of concepts, embodiments, or results. They do not define or limit the scope of invention. They are not drawn to any absolute or relative scale. In some cases, identical or similar reference numbers may be used for identical or similar features in multiple drawings.

FIG. 1 is a simplified block diagram of a resistive-switching non-volatile memory cell.

FIG. 2 is a conceptual graph illustrating temperature process windows for a pair of hypothetical precursors.

FIG. 3 is a block diagram of an example ALD or CVD apparatus.

FIGS. 4A-4C conceptually illustrate deposition of a reacted sub-layer from a low-temperature precursor layer by sequential pulses of the LTP and the reactant (i.e., the oxidizer/nitridizer).

FIGS. 5A-5B illustrate formation of a reacted sub-layer by simultaneously injecting the LTP and the reactant (i.e., the oxidizer/nitridizer) into the chamber.

FIGS. 6A-6E conceptually illustrate laminate formation of reacted and physisorbed sub-layers, annealing, and the resulting compound layers.

FIGS. 7A and 7B are flowcharts for example processes forming complex compound layers.

### DETAILED DESCRIPTION OF EXAMPLE EMBODIMENTS

A detailed description of one or more example embodiments is provided below. To avoid unnecessarily obscuring the description, some technical material known in the related fields is not described in detail. Semiconductor fabrication generally requires many other processes before and after those described; this description omits steps that are irrelevant to, or that may be performed independently of, the described processes.

Unless the text or context clearly dictates otherwise: (1) By default, singular articles “a,” “an,” and “the” (or the absence of an article) may encompass plural variations; for example, “a layer” may mean “one or more layers.” (2) “Or” in a list of multiple items means that any, all or any combination of less than all the items in the list may be used in the invention. (3) Where a range of values is provided, each intervening value is encompassed within the invention. (4) “About” or “approximately” contemplates up to 10% variation. “Substantially” contemplates up to 5% variation.

“Substrate,” as used herein, may mean any workplace on which formation or treatment of material layers is desired. Substrates may include, without limitation, silicon, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “water” may be used interchangeably herein. Semiconductor wafer shapes and sizes can vary and include commonly used round wafers of 50 mm, 100 mm, 150 mm, 200 mm, 300 mm, or 450 mm in diameter. “Film” and “layer” are synonyms representing a portion of a stack, and may mean either a single layer or a portion of a slack with multiple sub-layers (e.g., a nanolaminate).

“High-k material”, “high-k layer”, and “high-k dielectric” are used interchangeably herein to refer to a material and/or layer with a dielectric constant (“k”) greater than 7. As used herein, “adsorb” may include chemisorption, physisorption, electrostatic or magnetic attraction, or any other interaction resulting in part of the precursor adhering to the substrate surface. “Physisorption” shall mean adsorption dominated by van der Waals forces, in which the electronic structure of the adsorbed atom or molecule is barely perturbed.

Herein, “constant resistance” as applied to a ReRAM embedded resistor layer means the resistance remains within 25% of a constant value when “read” or “write” signals are applied during ReRAM operation. Herein, “variable resistance” as applied to a ReRAM resistive-switching layer means the resistance switches between at least two stable states when a write signal is applied, but remains constant when a “read” signal is applied, during ReRAM operation.

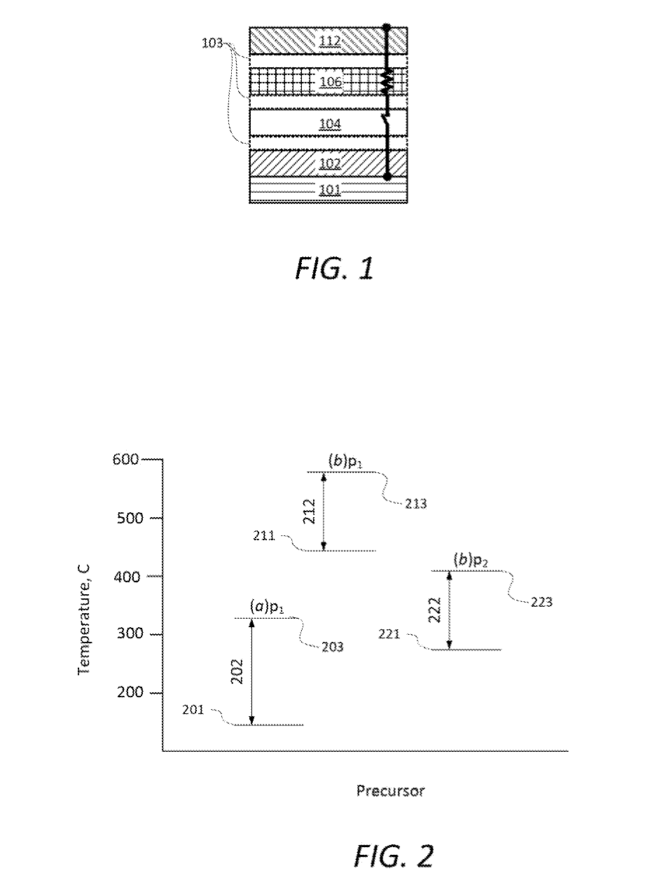

FIG. 1 is a simplified block diagram of a resistive-switching non-volatile memory cell. This is a non-limiting example of an application that could make use of complex oxide, nitride, or oxynitride materials; other applications could also use them. Substrate 101 may include additional layers and structures beneath the memory cell. Outer electrodes 102 and 112 are conductive layers that may form contacts with the word-lines and bit-lines that select the particular cell to read or write. Variable-resistance layer 104 switches between at least two stable states—a low-resistance state and a high-resistance state—responsive to a “write” signal transmitted through electrodes 102 or 112. For example, a conductive filament may form within variable-resistance layer 104 to produce the low-resistance state, and may break or dissipate to produce the high-resistance state. However, the resistance of variable-resistance layer 104 does not change in response to a “read” signal.

Optionally, a constant-resistance layer 106 may be included to prevent excessive current from flowing through variable-resistance layer 104. Excessive current could potentially create an indestructible filament, leaving the cell permanently locked in a low-resistance state. Constant-resistance layer 106 acts like a resistor connected in series with the switch created by variable-resistance layer 104, and does not change its resistance significantly (i.e., by more than 25%) in response to either “read” or “write” signals.

In addition, any number of intervening layers 103 may be formed between electrodes 102 and 112: barrier layers to prevent inter-layer reactions or diffusion of metals or oxides, buffer layers, defect-access layers, doping layers, diodes or other current-steering components, intermediate electrodes, and others.

It is believed that some complex compounds may enable better performance of existing layers; for example, a TaSiN constant-resistance layer with increased Si content may be more thermally stable and exhibit increased breakdown strength. In addition, use of some complex compounds but may simplify fabrication by allowing some layers to be eliminated or others to perform multiple functions: for example, a TaSiN layer with a gradient distribution of Si could operate as both an electrode (with low Si at the conductive-contact interface) and as a constant-resistance layer (with high Si away from the conductive-contact interface). As another example, a gradient of HfOx to HfSiN could create a built-in constant-resistance layer with the variable-resistance layer.

FIG. 2 is a conceptual graph illustrating temperature process windows for a pair of hypothetical precursors. A generalized ternary oxynitride can be expressed as (a)(b)OₓN_{y} where (a) and (b) may be any suitable element other than oxygen or nitrogen. In ReRAM applications, (a) and (b) are often metals, metalloids, semiconductors, or rare-earth elements. For the limiting case of a nitride, x=0, and for the limiting case of an oxide, y=0.

In the illustrated example, a precursor (a)p₁ for material (a) does not produce the desired reaction (with oxygen, nitrogen, or both) below temperature 201 (T_{min, (a)p1}). It does react if the temperature is within range 202, and it dissociates, decomposes, or is otherwise compromised in its effectiveness of deposition or reaction above temperature 203 (T_{max, (a)p1}). Range 202 can be considered the “process window” for precursor (a)p₁. Meanwhile (b)p₁, a precursor for (b), does not produce the desired reaction below temperature 211 (T_{min, (b)p1}), does react in its process-window range 212, and encounters problems above temperature 213 (T_{max, (b)p1}).

Thus, between (a)p₁ and (b)p₁, (a)p₁ is the low-temperature precursor (LTP) and (b)p₁ is the high-temperature precursor (HTP). For example, (a)p₁ may be a metal-organic precursor such as TBTDETa and (b)p₁ may be an inorganic precursor such as silane or disilane. There is no temperature that is within both of the process windows 202 and 212; (a)p₁'s maximum temperature 203 is well below (b)p₁'s minimum temperature 211. Therefore, co-deposition of (a) from (a)p₁ and (b) from (b)p₁ is very difficult. It might be possible to heat the substrate to just below T_{max, (a)p1} 203, form (a)OₓN_{y}, heat the substrate to just above T_{min, (b)p1} 211, form (b)OₓN_{y}, and attempt to interdiffuse the layers, but the temperature change could add process time, especially if done repeatedly, and bond strength of the fully-reacted layers may make interdiffusion difficult.

In some instances, another precursor (e.g., (b)p₂ in FIG. 2) may be available that has a process window overlapping that of (a)p₁ and does not present obstacles of its own (e.g., excessive expense, toxicity, or handling difficulty). As illustrated, (b)p₂'s minimum temperature T_{min, (b)p2} 221 is less than T_{max, (a)p1} 203, so between temperatures 221 and 203 (a)p₁ and (b)p₂ could be co-deposited. Alternatively there may be some other precursor for (a) with a process window overlapping that of (b)p₁. This may not always be possible.

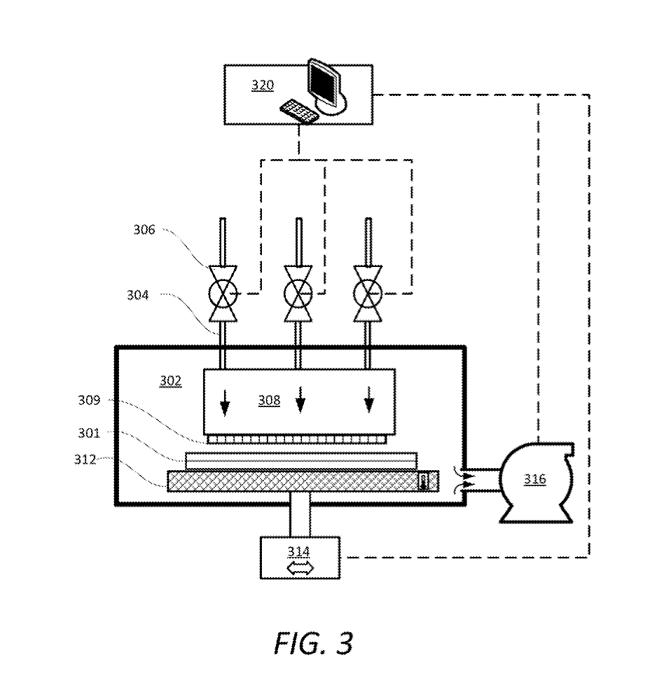

FIG. 3 is a block diagram of an example ALD or CVD apparatus. For clarity, some components that may be included with some ALD or CVD chambers, such as a substrate-loading port, substrate lift pins, and electrical feedthroughs, are not shown. Environmentally-controlled process chamber 302 contains substrate holder 312 to hold substrate 301 for processing. Substrate holder 312 may be made from a thermally conducting metal (e.g., tungsten, molybdenum, aluminum, nickel) or other like materials (e.g., a conductive ceramic) and may be temperature-controlled. Drive 314 may move substrate holder 312 (e.g., translate or rotate in any direction) during loading, unloading, process set-up, or sometimes during processing.

Process chamber 302 is supplied with process gases by delivery lines 304 (although three are illustrated, any number of delivery lines may be used). A valve and/or mass flow controller 306 may be connected to one or more of delivery lines 304 to control the delivery rates of process gases into process chamber 302. In some embodiments, gases are routed from delivery lines 304 into process chamber 302 through delivery port 308. Delivery port 308 may be configured to premix the process gases (e.g., precursors and diluents), shape the distribution of the process gases over the surface of substrate 301, or both. Delivery port 308, sometimes called a “showerhead,” may include a diffusion plate 309 that distributes the process gases through multiple holes. Vacuum pump 316 exhausts reaction products and unreacted gases from, and maintains the desired ambient pressure in, process chamber 302.

Chamber 320 may be connected to control various components of the apparatus to produce a desired set of process conditions. Controller 320 may include one or more memory devices and one or more processors with a central processing unit (CPU) or computer, analog and/or digital input/output connections, stepper motor controller boards, and the like. In some embodiments, controller 320 executes system control software including sets of instructions for controlling timing, gas flows, chamber pressure, chamber temperature, substrate temperature, radio frequency (RF) power levels (if RF components are used, e.g., for process gas dissociation), and other parameters. Other computer programs and instruction stored on memory devices associated with controller 320 may be employed in some embodiments.

ALD films, being deposited in monolayers, often exhibit smoother surfaces than layers made by other methods. For example, an ALD layer may have a surface roughness less than 0.3 nm rms (measured by, e.g., atomic force microscopy).

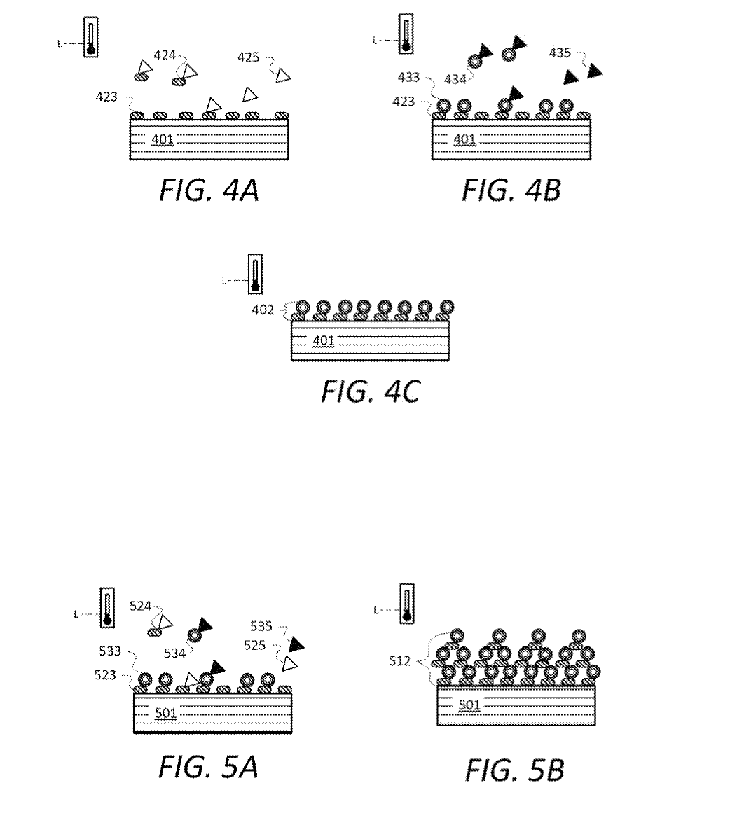

FIGS. 4A-4C conceptually illustrate deposition of a reacted sub-layer from a low-temperature precursor layer by sequential pulses of the LTP and the reactant (i.e., the oxidizer/nitridizer). These illustrations are highly symbolic and not intended to accurately resemble any particular atoms or molecules. The substrate is prepared in a chamber at a temperature L within the reaction temperature range of the LTP (i.e., T_{min,LTP}<L<T_{max,LTP}) In FIG. 4A, a pulse of LTP 424 is injected into the chamber. Deposited material 423 (e.g., material A) adsorbs to substrate 401 and any LTP ligands 425 not intended for deposition are released. Optionally, the chamber may then be purged of any unreacted LTP 424, ligands 425, or other by-products. In FIG. 4B, a pulse of reactant 434 is injected into the chamber. Because temperature L is within the reaction temperature range of the LTP, oxygen and/or nitrogen 433 reacts with deposited material 423 (e.g., element (a)) to form (a)OₓN_{y}, and any ligands 435 are released. Optionally, the chamber may then be purged of any unreacted reactant 434, ligands 435, or other by-products. In FIG. 4C, a sub-layer 402 of (a)OₓN_{y} is formed. Sub-layer 402 may be a monolayer, a sub-monolayer (with less than all the available reactive sites occupied) or several monolayers.

FIGS. 5A-5B illustrate formation of a reacted sub-layer by simultaneously injecting the LTP and the reactant (i.e., the oxidizer/nitridizer) into the chamber. As with the sequential injection method of FIGS. 4A-4C, the chamber is kept at a temperature L within the reaction range of the LTP. In FIG. 4D, both the LTP 424 and the reactant 434 are present in the chamber, allowing both deposited material 423 and oxygen/nitrogen 433 to adsorb to substrate 401 and releasing any ligands 425, 435. In FIG. 4E, the seed sub-layer 412 of (a)OₓN_{y} is formed.

For simplicity, the illustrations show a single LTP and a single reactant, each contributing a single material to the seed sub-layer; however, in some embodiments there may be more than one of each. Inert gases, such as carrier or buffer gases (e.g., argon (Ar)) are also not shown, but may be present in the chamber at one or more stages of the process.

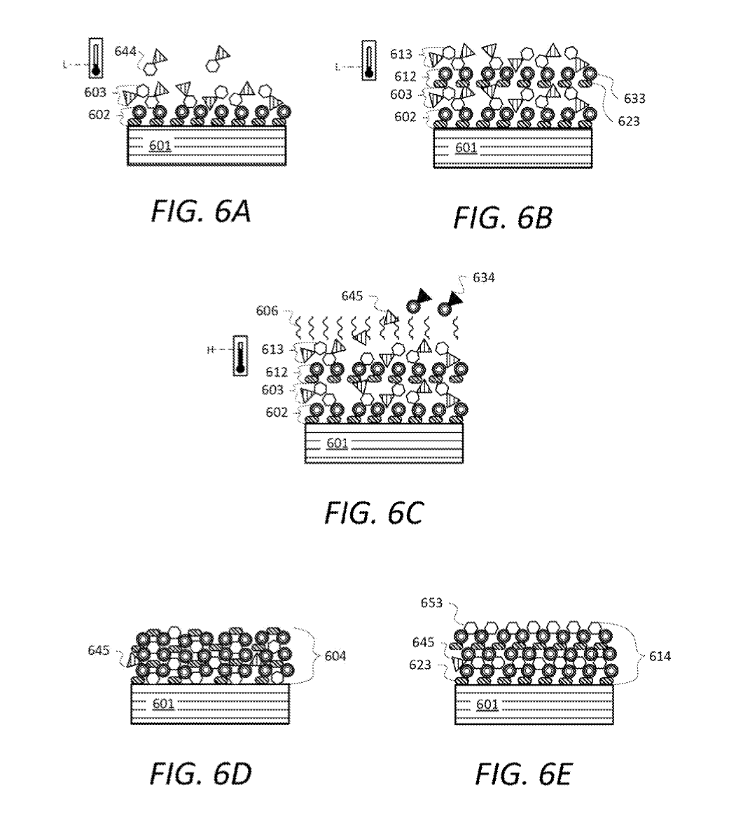

FIGS. 6A-6E conceptually illustrate laminate formation of reacted and physisorbed sub-layers, annealing, and the resulting compound layers. In FIG. 6A, substrate 601 has a reacted sub-layer 602 of (a)OₓN_{y}, which may be deposited by one of the methods (alternate pulses or co-injection of the LTP and the reactant) described with reference to FIG. 4. High-temperature precursor (HTP) 644 is injected into the chamber. The chamber temperature remains at level L, which is within the reaction range of the LTP (424 in FIGS. 4A-E), but is below the reaction range of HTP 644. HTP 644 therefore cannot react with layer 602, but may physisorb onto reacted sub-layer 602 to form physisorbed sub-layer 603. Physisorption may be encouraged by chamber pressure (˜1-1.5 Torr) or in some embodiments by an electrostatic or magnetic field at the surface of seed sub-layer 602. In particular, chamber pressure may encourage physisorption on non-horizontal surfaces, such as sidewalls of 3D structures on the substrate. HTP 644 may, may not, or may partially separate its deposited material (e.g., element (b)) from its ligand(s) in the process of physisorption.

In some embodiments, the pair of sub-layers in FIG. 6A may produce a desired film thickness. If a thicker layer is desired, or if more materials need to be added (e.g., material (c) to form (a)(b)(c)OₓN_{y}), additional sub-layers may optionally be formed. In FIG. 6B, an additional reacted sub-layer 612 has been formed above physisorbed sub-layer 603 from deposited material 623, 633 from an LTP and a reactant. The LTP and reactant may be the same ones used for reacted seed sub-layer 602, or they may be different. An additional physisorbed sub-layer 613 has also been formed above additional reacted sub-layer 612. The HTP may be the same one used for physisorbed sub-layer 603, or it may be different. Any number of reacted sub-layers and physisorbed sub-layers can be formed until the desired thickness (e.g., 1-20 nm) is reached. Optionally, multiple LTPs, reactants, or HTPs may be used for each layer. All the layers may be formed within a range of temperatures L conducive to reactions of the LTP(s) with the reactant(s), the substrate, or both.

In FIG. 6C, the substrate, with its stack of sub-layers, is heated to a higher temperature H at which HTP(s) 644 in physisorbed sub-layer(s) 603, 613 can react with the reactant(s). In some embodiments, the reacted oxide, nitride, or oxynitride in sub-layers 602, 612 is more temperature-tolerant than its originating LTP. Heat 606 may drive off at least some HTP ligands 645. Some ligands 645, such as the hydrogen atoms from silane (SiH₄), can diffuse through overlying layers. Alternatively, some ligands 645, such as hydrogen and fluorine, are able to passivate dangling bonds in certain dielectrics and may be useful to partially retain.

Optionally, the anneal can be done in an atmosphere containing additional reactant(s) 634 if a higher O or N content is desired in the complex compound. In some embodiments, it may be desirable to have a lower O or N content to provide oxygen or nitrogen vacancies; for example, to form the filament in a variable-resistance material, or to raise the conductivity of a barrier layer in a metal-insulator-semiconductor contact (see, e.g., co-pending U.S. patent application Ser. No. XX/XXX,XXX filed XX XXX XXXX and having assignee docket no. IM1186). For those applications, the anneal reactant 634 can be omitted, and reacted sub-layers 602, 612 may optionally be “reactant-starved” by using shortened pulses, reduced flow rates, or less-reactive precursors for the O or N.

In some embodiments, the finished complex-compound layer of (a)(b)OₓN_{y} (or a more complex material (a)(b)(c)OₓN_{y}, (a)(b)(c)(d)OₓN_{y}, etc.) has thoroughly interdiffused components as in layer 604 of FIG. 6D. In some embodiments, strata richer in one of the component materials (a) or (b) (523 or 653) may be detectable as shown in FIG. 6E, but compound layer 614 nevertheless behaves (electrically, optically, mechanically, or in any sense relevant to performance in the chosen application) as an (a)(b)OₓN_{y} alloy. Some trapped ligands 645 may or may not be present in either type of compound layer.

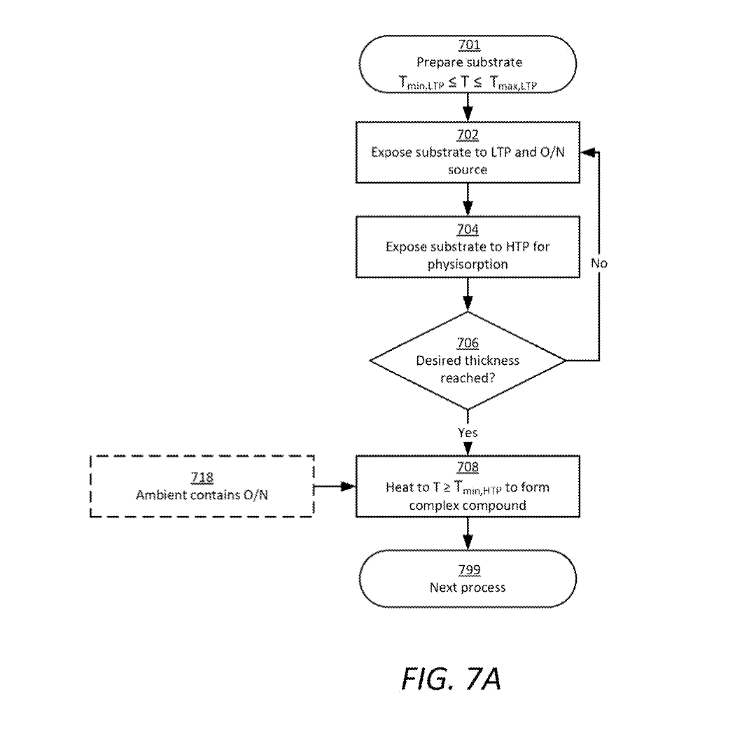

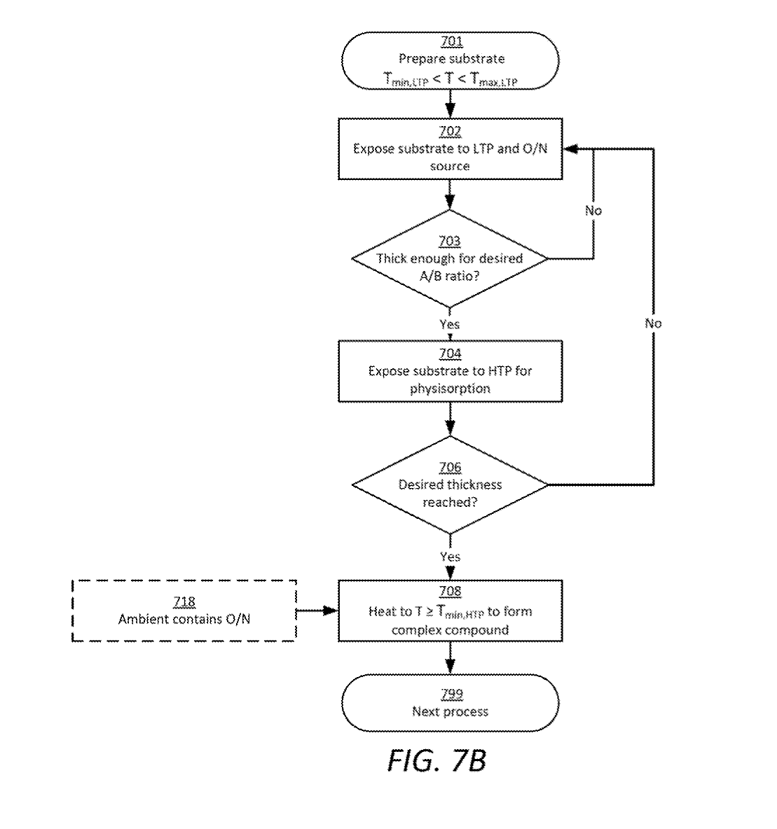

FIGS. 7A and 7B are flowcharts for example processes forming complex compound layers. FIG. 7A illustrates a general process. A substrate is prepared 701 and placed in a process chamber at a temperature T within the LTP's reaction range (i.e., T_{min,LTP}≦T≦T_{max,LTP}). For example, T may be between 200 and 400 C, or between 200 and 300 C. The substrate is exposed 702 to the LTP and to a source of oxygen, nitrogen, or both. Exposure 702 may be sequential, by alternating pulses of the LTP and the O/N source, optionally interspersed with purges of the chamber that may use an inert gas such as Ar. Alternatively, exposure 702 may be simultaneous, with the LTP and the O/N source being co-injected or otherwise present at the substrate at the same time. Exposure 702 forms a reacted sub-layer (e.g., (a)OₓN_{y}). In some embodiments, the reacted sub-layer is formed by ALD or CVD.

With the temperature still within the LTP's reaction range, the substrate is exposed 704 to the HTP and the HTP is allowed to physisorb, forming a physisorbed sub-layer. In some embodiments, the HTP may itself include O or N; for example, trisilylamine ((SiH₃)N, Si₃H₉N, “TSA”) includes both Si and N. Until the desired layer thickness is reached 706, the process is repeated to form additional reacted sublayers and physisorbed sublayers. For example, a desired layer thickness may be 3-20 nm.

After the desired layer thickness is reached 706, the substrate is heated 708 to a temperature at which the HTP reacts (e.g., T≧T_{min,HTP}). For example, T may be between about 400 and 750 C. In some embodiments, the HTP may react only with the O and/or N already present in the reacted sublayers. In some embodiments, the substrate may be heated 708 in an ambient 718 that includes O and/or N, and the HTP may react with the O and/or N in the ambient. Ambient 718 may include the same reactant used to form one or more of the reacted sub-layers, or it may include a different reactant. In some embodiments, the sub-layers may interdiffuse as well as reacting. Once sufficient reaction has taken place for a desired O and/or N content in the layer, the next process may commence 799.

In FIG. 7B, the composition of the complex compound layer is tuned by the distribution of reacted sublayers and physisorbed sublayers in the laminate. The substrate is prepared 701 in the chamber with T_{min,LTP}≦T≦T_{max,LTP}, and exposed 702 to the LTP and the O/N source (simultaneously, or sequentially with or without purges). If the complex compound layer is intended to have more of the deposited material from the LTP than from the HTP (e.g., more A than B), the continuous exposure may continue, or the sequential exposures may repeat, until the reacted sublayer reaches a desired thickness 703. Then the physisorbed sublayer is formed 704 and more reacted sublayers and physisorbed sublayers are overlaid until the entire layer reaches a desired thickness 706. At that point the substrate is heated 708 in an optional O/N ambient 718. Once sufficient reaction has taken place for a desired O and/or N content in the layer, the next process may commence 799.

Other ways to tune the composition of the complex-compound layer include changing the HTPs (using different precursors for the same material) and the anneal gases. For example, silicon precursors vary in the amount of Si they incorporate into a deposited layer; disilane, with its two closely coupled Si atoms, deposits denser Si than silane, where a single Si atom is surrounded by H atoms. Anneal gases can contribute more or less O or N depending on their dissociation energies: N₂, fairly stable, results in a light additional nitridation, whereas NH₃ is easier to dissociate and thereby results in heavier nitridation, and N₂H₅ is still easier to dissociate and thus a more aggressive agent of nitridation.

Sub-layer distributions and component precursors may be varied from one part of the layer to another, resulting in depth-wise composition gradients. For example, a TaSiN layer may be Ta-rich at the bottom and Si-rich at the top from sub-layer distributions, depositing Si from silane at the bottom and disilane at the top, or both. The anneal gas can cause composition gradients in thick layers; N or O from the anneal gas can percolate through layers less than about 20 nm, but depending on the film density it may not penetrate to the bottom of a thick layer, so the thick layer may have more N and/or O at the top as a result of annealing in N and/or O.

LTPs for these processes may include precursors for Ta, Hf, titanium (Ti), zirconium (Zr), chromium (Cr), strontium (Sr) and others. HTPs may include precursors for Si, germanium (Ge), aluminum (Al), gallium (Ga), and others. Reaction temperatures for various precursors with O and N are known in the ALD and CVD art, so that one of ordinary skill may readily derive variations that, while not specifically mentioned here, still fall within the scope of invention.

Material and Process Examples

Hafnium-Silicon Oxide: Set T˜300-325 C. Expose the substrate (step 702) to tetrakis[dimethylamino]hafnium (Hf[N(CH₃)₂]₄, TDMAHf, the LTP) and water (H₂O, the reactant O source) to form a HfOₓ reacted sub-layer (x will depend on whether enough O is made available to saturate the available Hf bonding sites). Expose the substrate (step 704) to tris[dimethylamino]silane (SiH[N(CH₃)₂]₃, 3DMAS, the HTP). The temperature is too low for 3DMAS to form a contiguous monolayer of silicon oxide; some of the precursor molecules reaching the surface may react, but the remainder will come to rest on the surface without reacting, forming a sublayer that is at least partially physisorbed. Deposit successive reacted sublayers and physisorbed sublayers to form the laminate. Heat the substrate (step 708) to a higher temperature, e.g., 400-700 C, for 1-5 min. Optionally, H₂O, oxygen (O₂), or ozone (O₃) may be present in the chamber during the heating to provide additional O.

Tantalum-Silicon Nitride: Set T˜290-325 C. Expose the substrate (step 702) to (tert-butylimido)tris(diethylamido)tantalum(V) (Ta[N(C₂H₅)₂]₃[═NC(CH₃)₃], TBTDETa, the LTP) and ammonia (NH₃, the reactant N source) to form a TaNₓ reacted sub-layer (x will depend on whether enough N is made available to saturate the available Ta bonding sites). Expose the substrate (step 704) to tris[dimethylamino]silane (SiH[N(CH₃)₂]₃, 3DMAS, the HTP). The temperature is too low for 3DMAS to form a contiguous monolayer of silicon oxide; some of the precursor molecules reaching the surface may react, but the remainder will come to rest on the surface without reacting, forming a sublayer that is at least partially physisorbed. Deposit successive reacted sublayers and physisorbed sublayers to form the laminate. Heat the substrate (step 708) to a higher temperature, e.g., 400-700 C, for 1-5 min. Optionally, NH₃ or N₂H₅ may be present in the chamber during the heating to provide additional N.

Tantalum-Silicon Nitride with Si Gradient: Set T˜290-325 C. Expose the substrate (step 702) to (tert-butylimido)tris(diethylamido)tantalum(V) (Ta[N(C₂H₅)₂]₃[═NC(CH₃)₃], TBTDETa, the LTP) and ammonia (NH₃, the reactant N source) to form a TaNₓ reacted sub-layer (x will depend on whether enough N is made available to saturate the available Ta bonding sites). Alternatively, the LTP may be pentakis dimethyamido tantalum (PDMATa). Expose the substrate (step 704) to one or more silicon-bearing HTPs. For example, the first exposure may be to silane, SiH₄. The temperature is too low for 3DMAS to form a contiguous monolayer of silicon oxide; some of the precursor molecules reaching the surface may react, but the remainder will come to rest on the surface without reacting, forming a sublayer that is at least partially physisorbed. Deposit successive reacted sublayers and physisorbed sublayers to form the laminate, but change the Si precursor when forming the physisorbed sublayers; for example, deposit a first set of physisorbed sublayers using silane alone, a second set using a mixture of silane and disilane, and a final set using disilane alone. Heat the substrate (step 708) to a higher temperature, e.g., 400-700 C, for 1-5 min. Optionally, NH₃ or N₂H₅ may be present in the chamber during the heating to provide additional N.

Although the foregoing examples have been described in some detail to aid understanding, the invention is not limited to the details in the description and drawings. The examples are illustrative, not restrictive. There are many alternative ways of implementing the invention. Various aspects or components of the described embodiments may be used singly or in any combination. The scope is limited only by the claims, which encompass numerous alternatives, modifications, and equivalents.

What is claimed is:

1. A method of forming a layer, comprising:
forming a first sub-layer by chemical reaction of a first precursor with a first reactant on a substrate at a first temperature;
forming a second sub-layer from a second precursor above the first sub-layer at the first temperature; and
heating the substrate to a second temperature;
wherein the second precursor requires a minimum temperature to react with the first reactant;
wherein the first temperature is less than the minimum temperature; and
wherein the second temperature is equal to or greater than the minimum temperature.

2. The method of claim 1, wherein the second precursor physisorbs to the first sub-layer during the forming of the second sub-layer, and wherein the second precursor reacts with the first reactant during the heating.

3. The method of claim 1, wherein the second temperature is above a decomposition temperature of the first precursor.

4. The method of claim 1, wherein the first sub-layer is formed by atomic layer deposition or chemical vapor deposition.

5. The method of claim 1, wherein a chamber pressure is between about 1 Torr and 1.5 Torr while forming the second sub-layer.

6. The method of claim 1, wherein the first temperature is between about 200 C and 400 C.

7. The method of claim 1, wherein the second temperature is between about 400 C and 750 C.

8. The method of claim 1, wherein the heating continues for between about 1 minute and about 5 minutes.

9. The method of claim 1, wherein a chamber ambient comprises a second reactant during the heating.

10. The method of claim 9, wherein the second reactant comprises an element present in the first reactant.

11. The method of claim 9, wherein some of the second reactant is incorporated into at least one of the sub-layers.

12. The method of claim 1, wherein a molecule of the first reactant comprises at least one atom of oxygen or nitrogen.

13. The method of claim 1, wherein the compound comprises an oxide, a nitride, or an oxynitride.

14. The method of claim 1, further comprising:
forming a third sub-layer by chemical reaction of the first precursor with the first reactant on a substrate at a first temperature;
forming a fourth sub-layer from a third precursor on the third sub-layer at the first temperature;
wherein the third precursor and the second precursor comprise a same metal, metalloid, semiconductor, or rare earth element; and

15. wherein a composition of the third precursor is not identical to the composition of the second precursor. The method of claim 1, further comprising forming additional sub-layers before the heating.

16. The method of claim 15, wherein a composition of the compound is tuned by a distribution of a number or thickness of the first sub-layers or the second sub-layers.

17. The method of claim 15, wherein a concentration of the second element, the oxygen, or the nitrogen varies with depth.

18. A layer formed on a substrate, the layer comprising:
a first element;
a second element; and
at least one of oxygen or nitrogen;
wherein the first element and the second element are not oxygen or nitrogen;
wherein a surface roughness of the layer is less than about 3 nm rms; and
wherein precursors for the first element and precursors for the second element do not react with the oxygen or the nitrogen at a same temperature.

19. The layer of claim 18, wherein the first element and the second element are each a metal, a metalloid, a semiconductor, or a rare-earth element.

20. The layer of claim 18, wherein a concentration of the second element, the oxygen, or the nitrogen varies with depth.
